(19) United States
(12) Patent Application Publication
(10) Pub. No.: US 2026/0039277 A1
(43) Pub. Date: Feb. 5, 2026

(54) MULTILAYER PIEZOELECTRIC SUBSTRATE DEVICE WITH IMPROVED TEMPERATURE STABILITY BY CAPACITOR

(71) Applicant: Skyworks Solutions, Inc., Irvine, CA (US)

(72) Inventors: Rei Goto, Osaka-Shi (JP); Yiliu Wang, Irvine, CA (US)

(21) Appl. No.: 19/287,713

(22) Filed: Jul. 31, 2025

Related U.S. Application Data
(60) Provisional application No. 63/679,000, filed on Aug. 2, 2024.

(51) Int. Cl. H03H 9/64; H03H 9/02; H03H 9/72

(52) U.S. Cl. CPC H03H 9/6483; H03H 9/02834; H03H 9/725

(57) ABSTRACT

An acoustic wave filter package with a surface acoustic wave resonator having a capacitor coupled in parallel with the surface acoustic wave resonator. The capacitor results in a shifted anti-resonant frequency.

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to multilayer piezoelectric substrate (MPS) devices, and in particular to MPS for surface acoustic wave (SAW) devices with an embedded interdigital transducer (IDT) structure having an additional capacitor coupled thereto to reduce a temperature coefficient of frequency (TCF) of the MPS.

### Description of the Related Technology

An acoustic wave device can include a plurality of resonators arranged to filter a radio frequency signal. Example acoustic wave resonators include SAW resonators and bulk acoustic wave (BAW) resonators. A surface acoustic wave resonator can include an interdigital transducer (IDT) electrode on a piezoelectric substrate. The surface acoustic wave resonator can generate a surface acoustic wave on a surface of the piezoelectric layer on which the interdigital transducer electrode is disposed. In BAW resonators, acoustic waves propagate in a bulk of a piezoelectric layer. Example BAW resonators include film bulk acoustic wave resonators (FBARs) and solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass fi(er. A plurality of acoustic wave filters can be arranged as a multiplexer. For example, three acoustic wave filters can be arranged as a triplexer. As another example, four acoustic wave filters can be arranged as a quadplexer.

Multilayer piezoelectric substrate (MPS) devices are developed to provide for ideal design of high Q, high coupling coefficient

$${k}_{eff}^{2} ,$$

small temperature coefficient of frequency (TCF) and high power durability filter solutions. A consolidated package is required allowing for additional freedom to design the ideal filter solutions.

### SUMMARY

In some aspects, the techniques described herein relate to a ladder filter including: an input port and an output port; a shunt surface acoustic wave resonator coupled between the input port and the output port and including a piezoelectric layer and an interdigital transducer structure; a series surface acoustic wave resonator coupled between the input port and the output port and including a piezoelectric layer, an interdigital transducer structure; and a capacitor coupled in parallel with the series surface acoustic wave resonator, the capacitor resulting in a shifted anti-resonant frequency for the series surface acoustic wave resonator.

In some aspects, the techniques described herein relate to a ladder filter wherein the capacitor has capacitance in a range between 0.1 and 3.9 pF.

In some aspects, the techniques described herein relate to a ladder filter wherein the capacitor and the interdigital transducer structure are separated by one or more reflectors.

In some aspects, the techniques described herein relate to a ladder filter wherein the capacitor and the interdigital transducer structure are formed in a same plane on the piezoelectric layer.

In some aspects, the techniques described herein relate to a ladder filter wherein the capacitor has fingers that are parallel or rotated with respect to fingers of the interdigital transducer structure.

In some aspects, the techniques described herein relate to a ladder filter wherein the capacitor and the interdigital transducer structure are formed in different planes on the piezoelectric layer.

In some aspects, the techniques described herein relate to a ladder filter wherein the interdigital transducer structure is at least partially embedded in the piezoelectric layer.

In some aspects, the techniques described herein relate to a ladder filter wherein the interdigital transducer structure has an embedment depth in a range between 0.01 and 0.1, where λ is a wavelength along an interdigital transducer propagation direction of a main mode.

In some aspects, the techniques described herein relate to a ladder filter wherein the interdigital transducer structure is fully embedded in the piezoelectric layer.

In some aspects, the techniques described herein relate to an acoustic wave filter package including: a package; a surface acoustic wave resonator within the package including a piezoelectric layer and an interdigital transducer structure; and a capacitor within the package and coupled in parallel with the surface acoustic wave resonator, the capacitor resulting in a shifted anti-resonant frequency.

In some aspects, the techniques described herein relate to an acoustic wave filter package wherein the capacitor has capacitance in a range between 0.1 and 3.9 pF.

In some aspects, the techniques described herein relate to an acoustic wave filter package wherein the capacitor and the interdigital transducer structure are separated by one or more reflectors.

In some aspects, the techniques described herein relate to an acoustic wave filter package wherein the capacitor and the interdigital transducer structure are formed in a same plane on the piezoelectric layer.

In some aspects, the techniques described herein relate to an acoustic wave filter package wherein the capacitor has fingers that are parallel or rotated with respect to fingers of the interdigital transducer structure.

In some aspects, the techniques described herein relate to an acoustic wave filter package wherein the capacitor and the interdigital transducer structure are formed in different planes on the piezoelectric layer.

In some aspects, the techniques described herein relate to an acoustic wave filter package wherein the interdigital transducer structure is at least partially embedded in the piezoelectric layer.

In some aspects, the techniques described herein relate to an acoustic wave filter package wherein the interdigital transducer structure has an embedment depth in a range between 0.01 and 0.1, where λ is a wavelength along an interdigital transducer propagation direction of a main mode.

In some aspects, the techniques described herein relate to an acoustic wave filter package wherein the interdigital transducer structure is fully embedded in the piezoelectric layer.

In some aspects, the techniques described herein relate to a mobile device including: a transceiver; an acoustic wave filter including a surface acoustic wave resonator including a piezoelectric layer and an interdigital transducer structure and further including a capacitor coupled in parallel with the surface acoustic wave resonator, the capacitor resulting in a shifted anti-resonant frequency; and an antenna.

In some aspects, the techniques described herein relate to a mobile device wherein the surface acoustic wave resonator is a series acoustic wave filter, the acoustic wave filter further including a shunt acoustic wave filter arranged in a ladder filter structure with the series acoustic wave filter.

In some aspects, the techniques described herein relate to a surface acoustic wave (SAW) filter package including: a piezoelectric layer; an interdigital transducer (IDT) structure; and an additional capacitor coupled to the IDT structure.

In some aspects, the techniques described herein relate to a SAW filter package wherein the additional capacitor has capacitance in the range between 0.1 and 3.9 pF.

In some aspects, the techniques described herein relate to a SAW filter package wherein the additional capacitor and the IDT structure are separated by one or more reflectors.

In some aspects, the techniques described herein relate to a SAW filter package wherein the additional capacitor and the IDT structure are formed in the same plane on the piezoelectric layer.

In some aspects, the techniques described herein relate to a SAW filter package wherein the additional capacitor has fingers that are parallel or rotated with respect to fingers of the IDT structure.

In some aspects, the techniques described herein relate to a SAW filter package wherein the additional capacitor and the IDT structure are formed in different planes on the piezoelectric layer.

In some aspects, the techniques described herein relate to a SAW filter package wherein the IDT structure is at least partially embedded in the piezoelectric layer.

In some aspects, the techniques described herein relate to a SAW filter package wherein the IDT structure includes a layer of molybdenum (Mo).

In some aspects, the techniques described herein relate to a SAW filter package wherein the IDT structure includes a layer of aluminum (Al).

In some aspects, the techniques described herein relate to a SAW filter package wherein the layer of Mo has a height in the range between 0.02 and 0.08, where A is a wavelength along an IDT propagation direction of a main mode.

In some aspects, the techniques described herein relate to a SAW filter package wherein the layer of Al has a height in the range between 0.04 and 0.08, where A is a wavelength along an IDT propagation direction of a main mode.

In some aspects, the techniques described herein relate to a SAW filter package wherein the IDT structure has an embedment depth in the range between 0.01 and 0.1, where λ is a wavelength along an IDT propagation direction of a main mode.

In some aspects, the techniques described herein relate to a SAW filter package wherein the piezoelectric layer includes lithium tantalate (LiTaO3, LT) or consists thereof.

In some aspects, the techniques described herein relate to a SAW filter package wherein the piezoelectric layer has an LT cut angle for XY—LiTaO3, where is in the range between approximately 20° and 60°, 360° being a full rotation.

In some aspects, the techniques described herein relate to a SAW filter package wherein the IDT structure includes a layer of copper (Cu).

In some aspects, the techniques described herein relate to a SAW filter package further including a piezoelectric layer capping the IDT structure.

In some aspects, the techniques described herein relate to a SAW filter package wherein the IDT structure has a reverse tapered shape.

In some aspects, the techniques described herein relate to a SAW filter package wherein the IDT structure includes a layer of copper (Cu), platinum (Pt), or gold (Au).

In some aspects, the techniques described herein relate to a SAW filter package further including a second piezoelectric layer capping the IDT structure.

In some aspects, the techniques described herein relate to a SAW filter package wherein the IDT structure is fully embedded in the piezoelectric layer.

In some aspects, the techniques described herein relate to a ladder filter including: an input port and an output port; and one or more surface acoustic wave (SAW) filter packages coupled in series between the input port and the output port, each of the one or more SAW filter packages including a piezoelectric layer, an interdigital transducer (IDT) structure, and an additional capacitor coupled to the IDT structure.

In some aspects, the techniques described herein relate to a ladder filter wherein the ladder filter includes one or more shunt resonators coupled to the series between the input port and the output port, wherein at least one of the shunt resonators includes an additional capacitor.

In some aspects, the techniques described herein relate to a ladder filter wherein the additional capacitor has capacitance in the range between 0.1 and 3.9 pF.

In some aspects, the techniques described herein relate to a ladder filter wherein the additional capacitor and the IDT structure are formed in the same plane on the piezoelectric layer.

In some aspects, the techniques described herein relate to a ladder filter wherein the additional capacitor has fingers that are parallel or rotated with respect to fingers of the IDT structure.

In some aspects, the techniques described herein relate to a ladder filter wherein the additional capacitor and the IDT structure are formed in different planes on the piezoelectric layer.

In some aspects, the techniques described herein relate to a ladder filter wherein the IDT structure is at least partially embedded in the piezoelectric layer.

In some aspects, the techniques described herein relate to a ladder filter wherein the IDT structure includes a layer of molybdenum (Mo).

In some aspects, the techniques described herein relate to a ladder filter wherein the IDT structure includes a layer of aluminum (Al).

In some aspects, the techniques described herein relate to a ladder filter wherein the layer of Mo has a height in the range between 0.02 and 0.08, where λ is a wavelength along an IDT propagation direction of a main mode.

In some aspects, the techniques described herein relate to a ladder filter wherein the layer of Al has a height in the range between 0.04 and 0.08, where λ is a wavelength along an IDT propagation direction of a main mode.

In some aspects, the techniques described herein relate to a ladder filter wherein the IDT structure has an embedment depth in the range between 0.01 and 0.1, where A is a wavelength along an IDT propagation direction of a main mode.

In some aspects, the techniques described herein relate to a ladder filter wherein the piezoelectric layer includes lithium tantalate (LiTaO3, LT) or consists thereof.

In some aspects, the techniques described herein relate to a ladder filter wherein the piezoelectric layer has an LT cut angle for XY—LiTaO3, where is in the range between approximately 20° and 60°, 360° being a full rotation.

In some aspects, the techniques described herein relate to a ladder filter wherein the IDT structure includes a layer of copper (Cu).

In some aspects, the techniques described herein relate to a ladder filter further including a piezoelectric layer capping the IDT structure.

In some aspects, the techniques described herein relate to a ladder filter wherein the IDT structure has a reverse tapered shape.

In some aspects, the techniques described herein relate to a ladder filter wherein the IDT structure includes a layer of copper (Cu), platinum (Pt), or gold (Au).

In some aspects, the techniques described herein relate to a ladder filter further including a second piezoelectric layer capping the IDT structure.

In some aspects, the techniques described herein relate to a ladder filter wherein the IDT structure is fully embedded in the piezoelectric layer.

In some aspects, the techniques described herein relate to a ladder filter wherein the additional capacitor and the IDT structure are separated by one or more reflectors

In some aspects, the techniques described herein relate to a mobile device including: a ladder filter including one or more surface acoustic wave (SAW) filter packages coupled in series between an input port and an output port of the ladder filter, each of the one or more SAW filter packages including a piezoelectric layer, an interdigital transducer (IDT) structure, and an additional capacitor coupled to the IDT structure.

In some aspects, the techniques described herein relate to a mobile device wherein the additional capacitor has a capacitance value in the range between 0.1 and 3.9 pF.

In some aspects, the techniques described herein relate to a mobile device wherein the additional capacitor and the IDT structure are separated by one or more reflectors.

In some aspects, the techniques described herein relate to a mobile device wherein the additional capacitor and the IDT structure are formed in the same plane on the piezoelectric layer.

In some aspects, the techniques described herein relate to a mobile device wherein the additional capacitor has fingers that are parallel or rotated with respect to fingers of the IDT structure.

In some aspects, the techniques described herein relate to a mobile device wherein the additional capacitor and the IDT structure are formed in different planes on the piezoelectric layer.

In some aspects, the techniques described herein relate to a mobile device wherein the IDT structure is at least partially embedded in the piezoelectric layer.

In some aspects, the techniques described herein relate to a mobile device wherein the IDT structure includes a layer of molybdenum (Mo).

In some aspects, the techniques described herein relate to a mobile device wherein the IDT structure includes a layer of aluminum (Al).

In some aspects, the techniques described herein relate to a mobile device wherein the layer of Mo has a height in the range between 0.02 and 0.08, where λ is a wavelength along an IDT propagation direction of a main mode.

In some aspects, the techniques described herein relate to a mobile device wherein the layer of Al has a height in the range between 0.04 and 0.08, where λ is a wavelength along an IDT propagation direction of a main mode.

In some aspects, the techniques described herein relate to a mobile device wherein the IDT structure has an embedment depth in the range between 0.01 and 0.1, where λ is a wavelength along an IDT propagation direction of a main mode.

In some aspects, the techniques described herein relate to a mobile device wherein the piezoelectric layer includes lithium tantalate (LiTaO3, LT) or consists thereof.

In some aspects, the techniques described herein relate to a mobile device wherein the piezoelectric layer has an LT cut angle for XY—LiTaO3, where is in the range between approximately 20° and 60°, 360° being a full rotation.

In some aspects, the techniques described herein relate to a mobile device wherein the IDT structure includes a layer of copper (Cu).

In some aspects, the techniques described herein relate to a mobile device further including a piezoelectric layer capping the IDT structure.

In some aspects, the techniques described herein relate to a mobile device wherein the IDT structure has a reverse tapered shape.

In some aspects, the techniques described herein relate to a mobile device wherein the IDT structure includes a layer of copper (Cu), platinum (Pt), or gold (Au).

In some aspects, the techniques described herein relate to a mobile device further including a second piezoelectric layer capping the IDT structure.

In some aspects, the techniques described herein relate to a mobile device wherein the IDT structure is fully embedded in the piezoelectric layer.

### BRIEF DESCRIPTION OF THE DRAWINGS

FIG. 1A is a cross sectional view of an IDT structure of a section of a SAW device having an IDT structure arranged on a piezoelectric layer.

FIG. 1B is an enlarged view of the encircled portion of the IDT shown in FIG. 1A.

FIG. 1C is a top view on a SAW device having e.g. the IDT structure illustrated in FIG. 1A.

FIG. 1D is a perspective view on a section of an IDT structure of a SAW device such as the SAW device shown in FIG. 1C.

FIG. 2A is a cross sectional view of an IDT structure of a section of a SAW device with a partially embedded IDT structure having two layers of Mo and Al or two layers of Cu and Al.

FIG. 2A′ is an enlarged view of the encircled portion of the IDT shown in FIG. 2A.

FIG. 2B is a cross sectional view of an IDT structure of a section of a SAW device with a fully embedded IDT structure having two layers of Mo and Al or two layers of Cu and Al where the fully embedded IDT structure is capped with a piezoelectric layer.

FIG. 2B′ is an enlarged view of the encircled portion of the IDT shown in FIG. 2B.

FIG. 2C is a cross sectional view of an IDT structure of a section of a SAW device with a partially embedded IDT structure having a layer of Cu, Pt, or Au where the IDT structure has a reverse tapered shape.

FIG. 2C′ is an enlarged view of the encircled portion of the IDT shown in FIG. 2C.

FIG. 2D is a cross-sectional view of an IDT structure of a section of another SAW device having multiple piezoelectric layers according to certain embodiments.

FIG. 3 shows qualitative plots of the admittance Y versus frequency f (frame A), the TCF versus frequency f (frame B), and the insertion loss IL versus frequency f (frames C, D) at different temperatures for the different filter structures.

FIG. 4 shows a plot of the TCF (frame A) and a plot of the static coupling

$${k}_{eff}^{2}$$

(frame B) for different additional capacitors C of exemplary filter structures.

FIG. 5A is a schematic diagram of a ladder filter according to an embodiment with exemplary additional capacitors.

FIG. 5B is a schematic diagram of another ladder filter according to an embodiment with exemplary additional capacitors.

FIG. 5C is a schematic diagram of yet another ladder filter according to an embodiment with exemplary additional capacitors.

FIG. 6 illustrates exemplary implementations of additional capacitors in relation to an IDT of a SAW device schematically illustrated in FIG. 1C.

FIG. 7 is a schematic diagram of a ladder filter according to another embodiment.

FIG. 8 is a schematic diagram of a lattice filter.

FIG. 9 is a schematic diagram of a hybrid ladder and lattice filter.

FIG. 10 is a schematic diagram of an acoustic filter that includes ladder stages and a multi-mode surface acoustic wave filter.

FIG. 11A is a schematic diagram of a duplexer that includes an acoustic wave filter according to an embodiment.

FIG. 11B is a schematic diagram of a multiplexer that includes an acoustic wave filter according to an embodiment.

FIG. 12 is a schematic diagram of a radio frequency module that includes an acoustic wave filter according to an embodiment.

FIG. 13 is a schematic block diagram of a module that includes an antenna switch and duplexers according to an embodiment.

FIG. 14 is a schematic block diagram of a module that includes a power amplifier, a radio frequency switch, and duplexers according to an embodiment.

FIG. 15 is a schematic block diagram of a module that includes a low noise amplifier, a radio frequency switch, and filters according to an embodiment.

FIG. 16 is a schematic diagram of a radio frequency module that includes an acoustic wave filter according to an embodiment.

FIG. 17A is a schematic block diagram of a wireless communication device that includes an acoustic wave filter according to an embodiment.

FIG. 17B is a schematic block diagram of another wireless communication device that includes an acoustic wave filter according to an embodiment.

The enclosed “Appendix” forms a part of this disclosure and describes certain embodiments and advantages of systems, methods, and methods provided in the Appendix and elsewhere herein.

### DETAILED DESCRIPTION OF EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic filters can implement bandpass filters. For example, a bandpass filter can be formed from temperature compensated (TC) surface acoustic wave (SAW) resonators. As another example, a bandpass filter can be formed from bulk acoustic wave (BAW) resonators, such as film bulk acoustic wave resonators (FBARs).

In acoustic filter applications, insertion loss improvement is typically desired by customers. Insertion loss improvement can help a receive chain with achieve a desired noise figure. Insertion loss improvement can help with implementing a transmit chain with less power consumption and/or better power handling.

Typical lithium tantalate (LiTaO₃, LT) based MPS SAW filter packages have an upper limit for

$${k}_{eff}^{2}$$

of around 12%. Inis value is nigher than the

$${k}_{eff}^{2}$$

for a 128° lithium niobate (LiNbO₃, LN) based MPS SAW filter package. However,

$${k}_{eff}^{2}$$

is still too small to obtain enough passband and good insertion loss. To obtain a

$${k}_{eff}^{2}$$

greater than 12%., a LN based MPS SAW filter package was proposed. Said LN based MPS had an attractive

$${k}_{eff}^{2}$$

greater than 15% but required a thick silicon dioxide (SiO₂) layer to compensate the LN's bad TCF likely resulting in a limited Q performance due to SiO₂ mechanical loss.

To provide a solution with a high

$${k}_{eff}^{2}$$

and a high Q, LT based MPS SAW filter packages with an embedded interdigital transducer (IDT) structure are proposed. Size reduction due to a large static capacitance may be achieved by embedding the IDT structure in a high permittivity piezoelectric substrate. Q performance may be maintained without requiring thick SiO₂.

Aspects of this disclosure relate to implementing an acoustic wave filter from more than one type of acoustic resonator. In certain embodiments, an acoustic wave filter can include series TCSAW resonators and shunt BAW resonators. Series TCSAW resonators can achieve higher quality factor (Q) in a frequency range below a resonant frequency (fs), while shunt BAW resonators can achieve a higher Q in a frequency range between fs and an anti-resonant frequency (fp). TCSAW resonators and/or BAW resonators may also be implemented in a stacked configuration.

Example SAW devices will now be discussed.

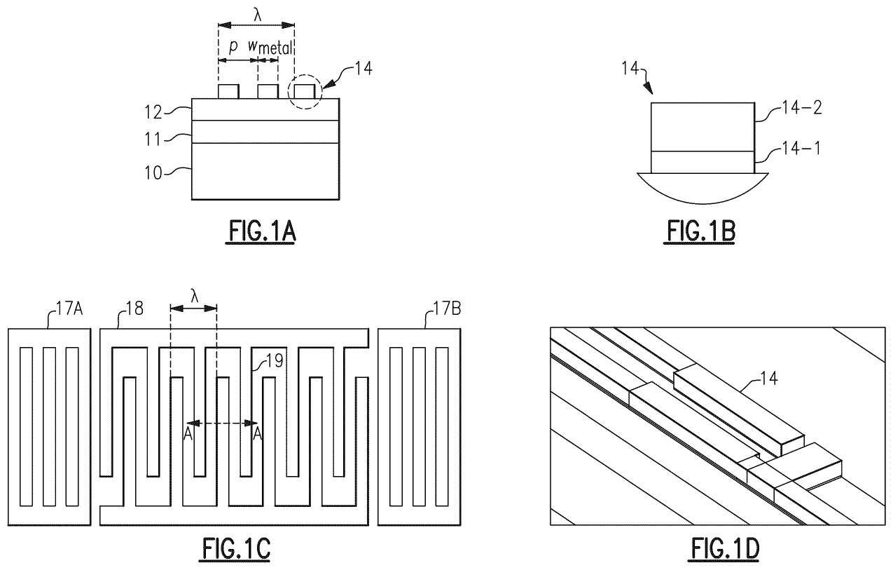

FIG. 1A is a cross sectional view of an IDT structure 14 of a section of a SAW device having a IDT structure 14 arranged on a piezoelectric layer 12. The SAW device can be a TCSAW resonator. As illustrated, the SAW device includes a piezoelectric layer 12 which may be formed over a layer of silicon dioxide (SiO₂) 11, and interdigital transducer (IDT) electrodes 14. The SiO₂ layer may be formed on a support substrate 10. The TCSAW device may comprise a temperature compensation layer over the IDT electrodes 14.

The piezoelectric layer 12 can be a lithium based piezoelectric layer. For example, the piezoelectric layer 12 can be a lithium niobate (LN) layer. As another example, the piezoelectric layer 12 can be a lithium tantalate (LT) layer.

In the TCSAW device, the IDT electrode 14 is over the piezoelectric layer 12. As illustrated, the IDT electrode 14 has a first side in physical contact with the piezoelectric layer 12 and a second side which may be in physical contact with the TC layer (not shown). The IDT electrode 14 can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrode 14 can be a multi-layer IDT electrode in some applications. A ratio of the IDT width (wₘₑₜₐₗ) to the pitch (p) is usually defined as duty factor (DF) or metallization ratio (wₘₑₜₐₗ/p).

In the TCSAW device, the TC layer can bring a temperature coefficient of frequency (TCF) of the TCSAW device closer to zero. The TC layer can have a positive TCF. This can compensate for a negative TCF of the piezoelectric layer 12. The piezoelectric layer 12 can be lithium niobate or lithium tantalate, which both have a negative TCF. The TC layer can be a dielectric film. The TC layer can be a silicon dioxide (SiO₂) layer. In some other embodiments, a different TC layer can be implemented. Some examples of other TC layers include a tellurium dioxide (TeO₂) layer or a silicon oxyfluoride (SiOF) layer.

FIG. 1B is an enlarged view of the encircled portion of the IDT electrode 14 shown in FIG. 1A. In the example shown in FIG. 1B, the IDT 14 electrode has two layers, for instance a layer 14-1 of molybdenum (Mo), and a layer 14-2 of aluminum (Al). The IDT 14 electrode as a whole is arranged on the piezoelectric layer 12.

FIG. 1C is a top view on a SAW device having e.g. an IDT electrode 14 illustrated in FIG. 1A. In FIG. 1C, the view of the SAW devices shown in FIG. 1A or FIG. 1B is along the dashed line from A to A. The TC layer is not shown in FIG. 1C. The IDT electrode 14 is positioned between a first acoustic reflector 17A and a second acoustic reflector 17B. The acoustic reflectors 17A and 17B are separated from the IDT electrode 14 by respective gaps. The IDT electrode 14 includes a bus bar 18 and IDT fingers 19 extending from the bus bar 18. The IDT fingers 19 have a pitch of p=λ/2, where λ denotes the wavelength of the resonant frequency fs of the SAW device. The SAW device can include any suitable number of IDT fingers 19. The pitch of the IDT fingers 19 corresponds to the resonant frequency fs of the SAW device.

FIG. 1D is a perspective view on a section of a rectangular IDT electrode 14 of a SAW device, such as a SAW device shown in FIG. 1C. The TC layer is not shown in FIG. 1D. A shown in FIG. 1D, a piston mode may be implemented as a hammerhead at end portions of the IDT structure 14.

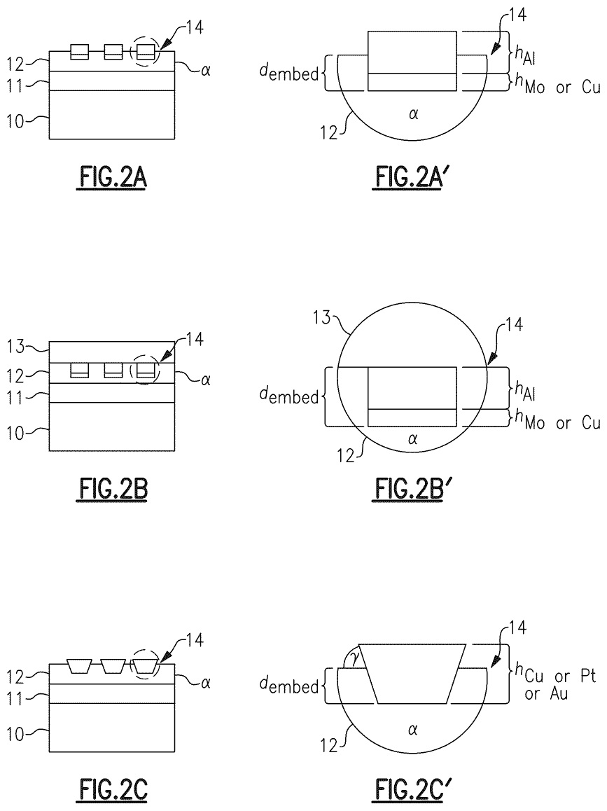

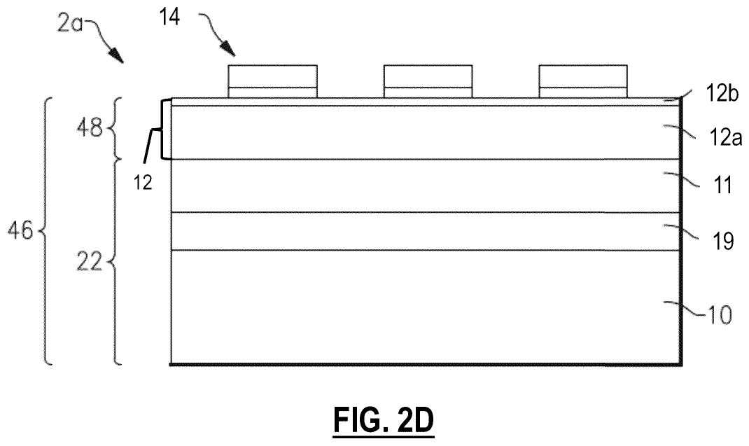

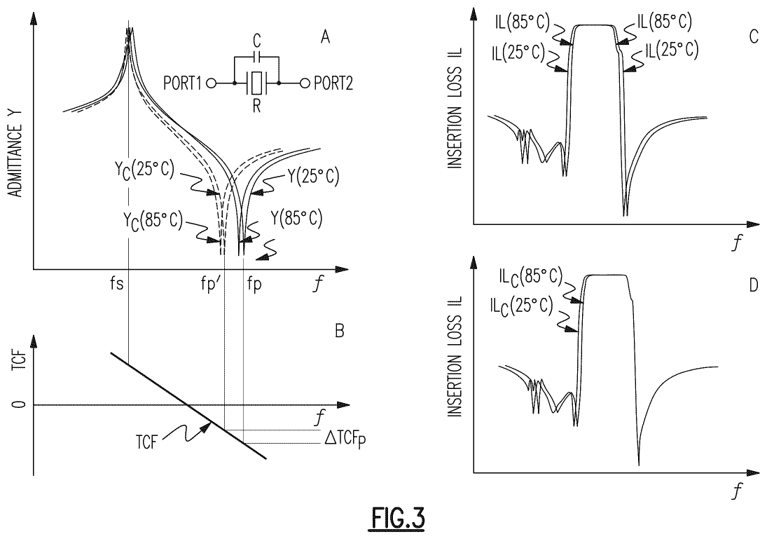

FIG. 2A is a cross sectional view of an IDT structure of a section of a SAW device with a partially embedded IDT structure having two layers of Mo and Al or two layers of Cu and Al. The IDT structure may be multi-layered in some applications. Mo, Cu, and Al are merely mentioned as examples.

The SAW device partly shown in FIG. 2A may comprise a support substrate 10, a layer of silicon dioxide (SiO₂) 11 formed on the support substrate 10, a piezoelectric layer 12 formed on the layer of SiO₂, and the partially embedded IDT structure 14. The piezoelectric layer 12 may comprise 42° XY—LiTaO₃ (42° XY—LT) or consist thereof. Alternatively or additionally, the piezoelectric layer 12 may comprise αXY—LT, or consist thereof, where α denotes the LT cut angle. The LT cut angle α may be in the range 0°≤α≤60°.

FIG. 2A′ is an enlarged view of the encircled portion of the IDT structure 14 shown in FIG. 2A. As shown in FIG. 2A′, in the case of two layers of Mo and Al, the layer of Mo has a height h_{Mo}, and the layer of Al has a height h_{Al}. The height h_{Mo} of the Mo layer may be in the range 0.02≤h_{Mo}/λ≤0.08, where λ corresponds to the geometry described in FIG. 1. The wavelength λ may be defined as the wavelength along an IDT propagation direction of a main mode. The main mode may be the mode that primarily contributes to form the filter characteristics. The height h_{Al} of the Al layer may be in the range 0.04≤h_{Al}/λ≤0.08, where λ is defined as above.

In the case of two layers of Cu and Al, the layer of Cu has a height h_{Cu}. The height h_{Cu} of the Cu layer may be in the range 0.02≤h_{Cu}/λ≤0.08, where λ is defined as above. The height h_{Al} of the Al layer may be in the range 0.04≤h_{Al}/λ≤0.08, where λ is defined as above. Cu can be used instead of Mo. Cu plating is suitable for embedding the IDT structure. Acoustic properties of Cu and Mo are similar.

The IDT structure 14 has an embedment depth d_{embed}. The embedment depth d_{embed} in the piezoelectric layer 12 may be in the range 0.00<d_{embed}/λ≤0.10, where λ is defined as above.

FIG. 2B is a cross sectional view of an IDT structure 14 of a section of a SAW device with a fully embedded IDT structure having two layers of Mo and Al or two layers of Cu and Al where the fully embedded IDT structure 14 is capped with a piezoelectric layer 13. Capping with a piezoelectric layer may increase a static capacitance which may be beneficial for size reduction.

The IDT structure 14 may be multi-layered in some applications. Mo, Cu, and Al are merely mentioned as examples.

The SAW device partly shown in FIG. 2B may comprise a support substrate 10, a layer of silicon dioxide (SiO₂) 11 formed on the support substrate 10, a piezoelectric layer 12 formed on the layer of SiO₂ and comprising the fully embedded IDT structure 14, and the piezoelectric layer 13 capping the fully embedded IDT structure 14. The piezoelectric layer 12 and the capping piezoelectric layer 13 may comprise 42° XY—LiTaO₃ (42° XY—LT) or consist thereof. Alternatively or additionally, the piezoelectric layers 12 and 13 may comprise αXY-LT, or consist thereof, where a denotes the LT cut angle. The LT cut angle α may be in the range 0°≤α≤50°. The LT cut angles of the piezoelectric layers 12 and 13 may also be different.

FIG. 2B′ is an enlarged view of the encircled portion of the IDT structure 14 shown in FIG. 2B. As shown in FIG. 2B′, in the case of two layers of Mo and Al, the layer of Mo has a height h_{Mo}, and the layer of Al has a height h_{Al}. The height h_{Mo} of the Mo layer may be in the range 0.02≤h_{Mo}/λ≤0.08, where λ corresponds to the geometry described in FIG. 1. The wavelength λ may be defined as the wavelength along an IDT propagation direction of a main mode. The main mode may be the mode that primarily contributes to form the filter characteristics. The height h_{Al} of the Al layer may be in the range 0.04≤h_{Al}/λ≤0.08, where A is defined as above.

In the case of two layers of Cu and Al, the layer of Cu has a height h_{Cu}. The height h_{Cu} of the Cu layer may be in the range 0.02≤h_{Cu}/λ≤0.08, where λ is defined as above. The height h_{Al} of the Al layer may be in the range 0.04≤h_{Al}/λ≤0.08, where λ is defined as above.

For the fully embedded IDT structure 14 the relation d_{embed}=h_{Mo or Cu}+h_{Al} holds.

FIG. 2C is a cross sectional view of an IDT structure of a section of a SAW device with a partially embedded IDT structure 14 having a layer of Cu, Pt, or Au where the IDT structure 14 has a reverse tapered shape. The reverse tapered IDT structure 14 may be multi-layered in some applications. Cu, Pt, or Au are merely mentioned as examples.

The SAW device partly shown in FIG. 2C may comprise a support substrate 10, a layer of silicon dioxide (SiO₂) 11 formed on the support substrate 10, a piezoelectric layer 12 formed on the layer of SiO₂, and the partially embedded IDT structure 14. The piezoelectric layer 12 may comprise 42° XY—LiTaO₃ (42° XY—LT) or consist thereof. Alternatively or additionally, the piezoelectric layer 12 may comprise αXY—LT, or consist thereof, where α denotes the LT cut angle. The LT cut angle α may be in the range 0°≤α≤50°.

FIG. 2C′ is an enlarged view of the encircled portion of the IDT 14 shown in FIG. 2C. As shown in FIG. 2C′, the layer of Cu, Pt, or Au has a height h_{Cu or Pt or Au}. The height h_{Cu or Pt or Au} of the Cu, Pt, or Au layer may be in the range 0.06≤h_{Mo}/λ≤0.16, where λ corresponds to the geometry described in FIG. 1. The wavelength A may be defined as the wavelength along an IDT propagation direction of a main mode. The main mode may be the mode that primarily contributes to form the filter characteristics.

The reverse tapered IDT structure 14 has an embedment depth d_{embed}. The embedment depth d_{embed} in the piezoelectric layer 12 may be in the range 0.00<d_{embed}/λ≤0.16, where λ is defined as above. The reverse tapered IDT structure 14 may be fully embedded in the piezoelectric layer 12. The SAW device partly shown in FIG. 2C may comprise a capping piezoelectric layer (not shown in FIG. 2C and FIG. 2C′) capping the fully embedded IDT structure 14.

The reverse tapered IDT structure 14 may have a reverse taper angle γ with respect to the surface of the piezoelectric layer 12. The reverse taper angle γ may be in the range 65°≤γ<90°, preferably at 75°. Different sides of the reverse tapered IDT structure 14 may have different reverse taper angles.

The reverse tapered IDT structure 14 may be formed starting out from SiO₂ or a-Si deposition on LT layer. The resulting substrate may be dry etched to form the shape of the reverse tapered IDT structure. A seed layer may then be deposited, followed by electroplating and planarization. In case of a-Si, XeF₂ gas may be used to remove a-Si.

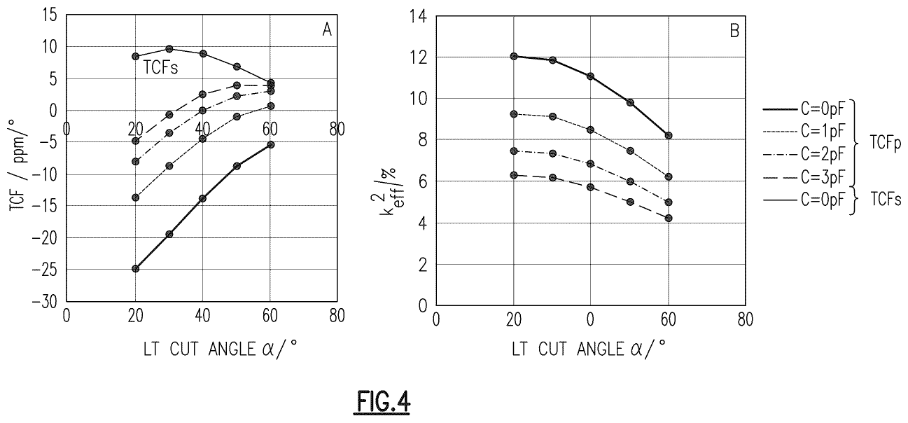

FIG. 2D is a cross-sectional view of an IDT structure 14 of a section of another SAW device 2a according to certain embodiments. Unless otherwise noted, components of FIG. 4 can be the same as or generally similar to the like components disclosed herein, such as those shown in FIG. 1A to 2C′. Unlike the devices of FIGS. 1A-2C′, the device 2a of FIG. 4 has a piezoelectric layer 12 including a first piezoelectric layer 12a and a second piezoelectric layer 12b. The SAW device 2a can include a support substrate 10, a trap rich layer 19, a functional layer 11 (e.g., an SiO₂ layer), a first piezoelectric layer 40, a second piezoelectric layer 12b, and an acoustic wave element 44, such as an interdigital transducer (IDT) electrode. The trap rich layer 19 and the functional layer 11 can be positioned between the support substrate 10 and the first piezoelectric layer 12a. The second piezoelectric layer 12 can at least partially (e.g., completely) cover an upper surface of the first piezoelectric layer 12a. The support substrate 10, the trap rich layer 19, the functional layer 11, the first piezoelectric layer 12a, and the second piezoelectric layer 12b can define a multilayer piezoelectric substrate (MPS) 46. The support substrate 10, the trap rich layer 19, and the functional layer 11 can define a support substrate structure 22 of the MPS 46, and the first and second piezoelectric layers 40, 42 can define a piezoelectric layer 12 (or a multi-piezoelectric layer structure) of the MPS 46.

Any of the SAW devices described herein, including those of FIGS. 1A-2C′ and FIGS. 3-17B, can be modified to include features of the device 2a, such as the trap rich layer 19 or the multiple piezoelectric layers 12a, 12b.

In some embodiments, the first and second piezoelectric layers 40, 42 can include lithium-based materials. For example, the first piezoelectric layer 40 can be a lithium tantalate (LT or LiTaO₃) layer and the second piezoelectric layer 42 can be a lithium niobate (LN or LiNbO₃). The IDT structure 14 can be in physical contact with the second piezoelectric layer 42.

FIG. 3 shows qualitative plots of the admittance Y versus frequency f (frame A) at different temperatures for different filter structures without and with (subscript C) an additional capacitor C, the TCF versus frequency f (frame B), and the insertion loss IL versus frequency f at different temperatures for the different filter structures without (frame C) and with (frame D) the additional capacitor C.

The admittance Y plotted in frame A shows that the filter structures have positive TCF at resonant frequency fs (TCFs) and negative TCF at anti-resonant frequency fp (TCFp). The TCF plotted in frame B shows that the TCF moves continuously from positive to negative values between the resonant frequency fs and anti-resonant frequency fp. Hence, near zero TCF exists between the resonant frequency fs and the anti-resonant frequency fp. In other words, frames A and B indicate that adding a capacitance to the filter structure, e.g., parallel to the IDT, reduces the absolute value of the anti-resonant frequency fp and moves the anti-resonant frequency fp towards the resonant frequency fs. By adding an additional capacitance to the filter structure, TCFp can be improved to values closer to zero.

FIG. 4 shows a plot of the TCF (frame A) and a plot of the static coupling

$${k}_{eff}^{2}$$

(frame B) for different additional capacitors C of exemplary filter structures at anti-resonant frequency fp (TCFp) and resonant frequency fs (TCFs) as a function of the LT cut angle α as obtained from a 2D simulation for a filter structure presented in FIG. 1A to FIG. 1D where a 1 μm layer of XY—LiTaO₃ is formed over a 1 μm layer of SiO₂ and the IDT with an aperture of 80 μm and 200 fingers arranged on the piezoelectric layer has two layers, a 100 nm layer of Mo and a 200 nm layer Al.

The additional capacitors may have a capacitance value in the range between 0.1 and 10 pF. In some implementations, the additional capacitors may have a capacitance value in the range between 0.1 and 3.9 pF.

TCF and

$${k}_{eff}^{2}$$

of the filter structures can be adjusted as needed based on either the LT cut angle α or the additional capacitors C of the filter structure or based on both the LT cut angle α and the additional capacitors C of the filter structure.

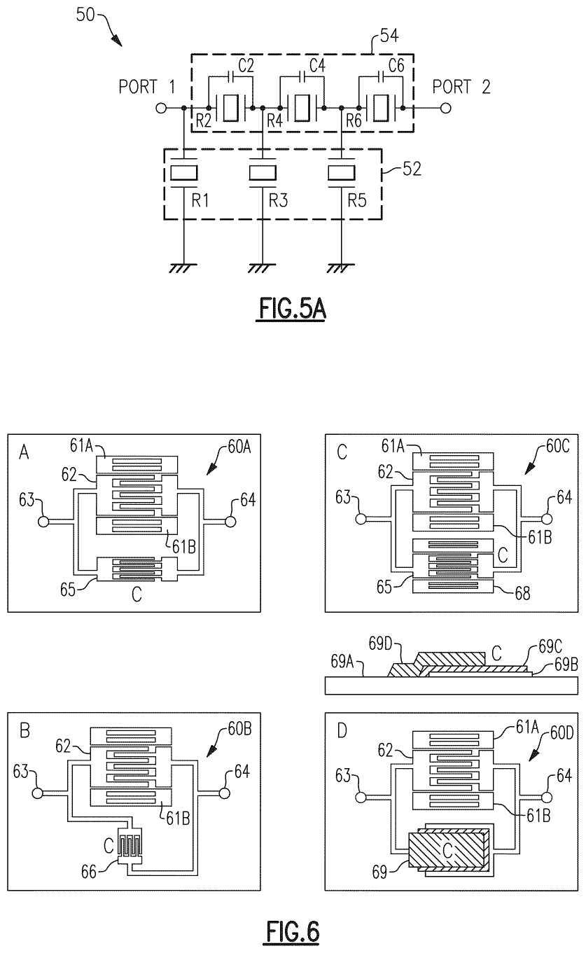

FIG. 5A is a schematic diagram of a ladder filter 50 according to an embodiment with exemplary additional capacitors. The ladder filter 50 includes one or more TCSAW resonators 54 coupled in series between RF input/output ports Port1 and Port2. The ladder filter 50 may include a shunt BAW resonators 52 coupled to the one or more TCSAW resonators 54 between the RF input/output ports Port1 and Port2. The ladder filter 50 is an example topology of a band pass filter formed from acoustic resonators. In a band pass filter with a ladder filter topology, the shunt resonators can have lower resonant frequencies than the series resonators. The ladder filter 50 can be arranged to filter an RF signal. As illustrated, the shunt BAW resonators may include resonators R1, R3, and R5. The illustrated series TCSAW resonators 54 include resonators R2, R4, and R6. One or more of the resonators R1 to R6 comprises an additional capacitor coupled in parallel with the respective one or more resonators.

As shown in FIG. 5A, R2, R4, and R6 may comprise an additional capacitor C2, C4, and C6, respectively. FIG. 5B is a schematic diagram of an alternative ladder filter 55 according to an embodiment with exemplary additional capacitors. In contrast to the ladder filter 50 of FIG. 5A, the ladder filter 55 of FIG. 5B only comprises additional capacitors C4 and C6 for the series resonators R4 and R6, respectively. FIG. 5C is a schematic diagram of an alternative ladder filter 57 according to an embodiment with exemplary additional capacitors. In contrast to the ladder filter 55 of FIG. 5B, the ladder filter 57 of FIG. 5C additionally comprises an additional capacitors C3 for the shunt resonator R3. In other implementations, any number of series resonators 54 may be provided with or without additional parallel capacitors. Moreover, in even further implementations, any number of shunt resonators 52 may be provided with or without additional parallel capacitors.

In particular, the TCSAW resonators 54 in FIGS. 5A, 5B, and 5C may be formed with features of any one or more of the IDTs shown in FIG. 2A to FIG. 2D. The first RF input/output port Port1 can be a transmit port for a transmit filter or a receive port for a receive filter. The second RF input/output port Port2 can be an antenna port. Any suitable number of series acoustic resonators with or without an additional capacitor can be in included in a ladder filter. Any suitable number of shunt acoustic wave resonators with or without an additional capacitor can be included in a ladder filter.

A higher number of capacitors C2 to C2n for the series resonators R2 to R2n may provide improved temperature drift because TCF is moved towards zero while proving steep filter cutoff enabled by small

$${k}_{eff}^{2} .$$

Additional capacitors C1 to C2m−1 for the shunt resonators R1 to R2n−1 with shunt IDT arms may provide lower filter steepness.

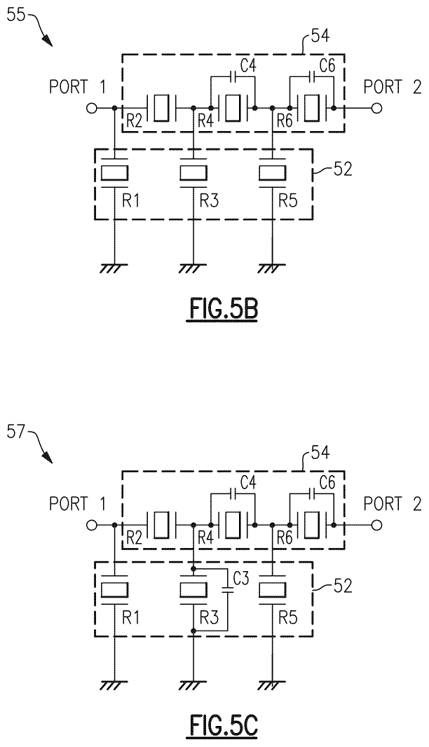

FIG. 6 illustrates exemplary implementations of additional capacitors in relation to an IDT electrode 62 of a SAW device schematically illustrated in FIG. 1C. Each of the SAW devices 60A, 60B, 60C, and 60D illustrated in the examples of frames A, B, C, and D, respectively, may include first acoustic reflectors 61A and second acoustic reflectors 61B sandwiching an IDT electrode 62. The SAW devices 60A, 60B, 60C, and 60D are each coupled between an input port 63 and an output port 64.

As shown in frame A, an additional capacitor 65 may be arranged in parallel to the IDT electrode 62 of the SAW device 60A such that e.g. fingers of the additional capacitor are parallel to the fingers of the IDT electrode 62. As shown in frame B, an additional capacitor 66 may also be arranged rotated with respect to the IDT electrode 62 of the SAW device 60B such that fingers of the additional capacitor 66 are oriented perpendicularly with respect to the fingers of the IDT electrode 62 of the SAW device 60B. As shown in frame C, one or more reflectors 68 may be arranged between the parallel capacitor 65 or rotated additional capacitor 66 and the IDT electrode 62 of the SAW device 60C.

As illustrated in frame D of FIG. 6, the additional capacitor 69 may be formed in the same plane as the IDT electrode 62 or in a plane that is different to the plane in which the IDT electrode 62 is formed. For example, an additional capacitor 69 may be formed on the substrate 69A on which the SAW device 60D is formed by depositing a bottom electrode layer 69B of the capacitor 69 on the substrate 69A, a dielectric layer 69C on top of the bottom electrode layer 69B of the capacitor 69, and a top electrode layer 69D of the capacitor 69 on the dielectric layer 69C.

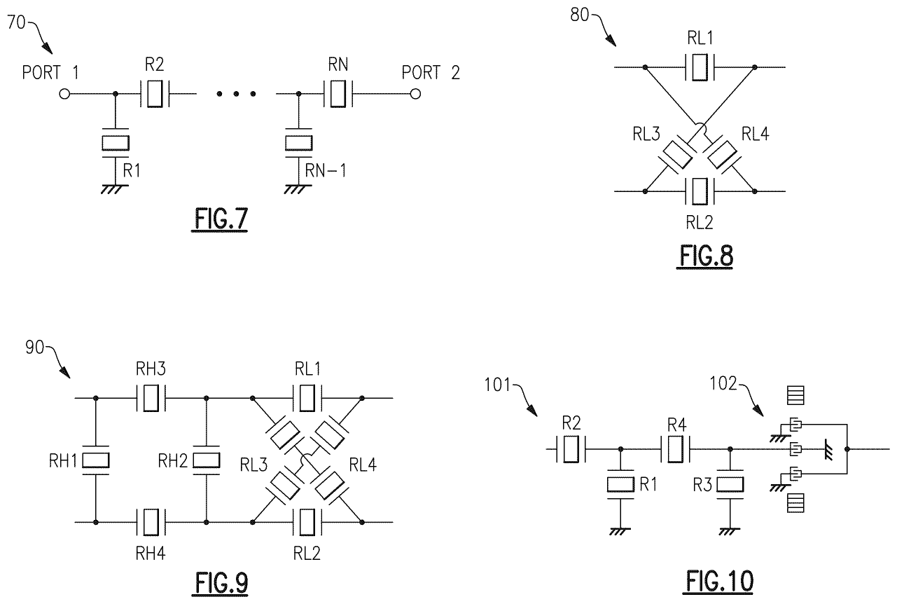

FIG. 7 is a schematic diagram of a ladder filter 70 according to another embodiment. The ladder filter 70 includes a plurality of acoustic resonators R1, R2, . . . , RN−1, and RN arranged between a first input/output port PORT1 and a second input/output port PORT1. One of the input/output ports PORT1 or PORT2 can be an antenna port. In certain instances, the other of the input/output ports PORT1 or PORT2 can be a receive port. In some other instances, the other of the input/output ports PORT1 or PORT2 can be a transmit port.

The ladder filter 70 illustrates that any suitable number of ladder stages can be implemented in a ladder filter in accordance with any suitable principles and advantages disclosed herein. Ladder stages can start with a series resonator or a shunt resonator from any input/output port of the ladder filter 70 as suitable. As illustrated, the first ladder stage from the input/output port PORT1 begins with a shunt resonator R1. As also illustrated, the first ladder stage from the input/output port PORT2 begins with a series resonator RN.

The ladder filter 70 includes shunt resonators R1 and RN−1 and series resonator R2 and RN. The series resonators of the ladder filter 70 including resonators R2 and RN can be acoustic resonators of a first type that have higher Q than series resonators of a second type in a frequency range below fs. The shunt resonators of the ladder filter 70 including resonators R1 and RN−1 can be acoustic resonators of the second type and have higher Q than shunt resonators of the first type in a frequency range between fs and fp. This can lead to a reduced insertion loss. The ladder filter 70 can be a band pass filter with series resonators of the first type and shunt resonators of the second type. In some other embodiments, the series resonators of the ladder filter 70 including resonators R2 and RN can be acoustic resonators of the second type and the shunt resonators of the ladder filter 70 including resonators R1 and RN−1 can be acoustic resonators of the first type. In such embodiments, the ladder filter 70 can be a band pass filter.

The resonators of the first type can be TCSAW resonators and the resonators of the second type can be BAW resonators. Accordingly, the ladder filter 70 can include series TCSAW resonators and shunt BAW resonators in certain embodiments. Such BAW resonators can include FBARs and/or solidly mounted resonators (SMRs). In particular, the TCSAW resonators of the ladder filter 70 may be formed with features of any one or more of the IDT structures shown in FIG. 2A to FIG. 2D.

The resonators of the first type can be multi-layer piezoelectric substrate (MPS) SAW resonators and the resonators of the second type can be BAW resonators. Accordingly, the ladder filter 70 can include series MPS SAW resonators and shunt BAW resonators. Such BAW resonators can include FBARs and/or SMRs in certain embodiments.

The resonators of the first type can be non-temperature compensated SAW resonators and the resonators of the second type can be BAW resonators. Accordingly, the ladder filter 70 can include series non-temperature compensated SAW resonators and shunt BAW resonators in certain embodiments. Such BAW resonators can include FBARs and/or SMRs.

In a bandpass filter with a ladder filter topology, such as the acoustic wave filter 70, the shunt resonators can have lower resonant frequencies than the series resonators. In certain embodiments, the shunt resonators of the acoustic wave filter 70 are BAW resonators and the series resonators of the acoustic wave filter 70 are TCSAW resonators. In such embodiments, the acoustic wave filter 70 can be a band pass filter. Such a bandpass filter can achieve low insertion loss at both a lower band edge and an upper band edge of a passband.

In a band stop filter with a ladder filter topology, such as acoustic wave filter 70, the shunt resonators can have higher resonant frequencies than the series resonators. In certain embodiments, the acoustic wave filter 70 is a band stop filter, the shunt resonators of the acoustic wave filter 70 are TCSAW resonators and the series resonators of the acoustic wave filter 70 are BAW resonators. Such a band stop filter can achieve desirable characteristics in a stop band of the band stop filter.

In some applications of an acoustic wave filter that includes TCSAW series resonators and BAW shunt resonators, such as a transmit filter with a relatively high power handling specification, one or more series resonators close to a transmit port (or the lower frequency series resonators) can be BAW resonators to help with ruggedness.

In certain applications, the ladder filter 70 can be included in a multiplexer in which relatively high γ for the ladder filter 70 in one or more higher frequency carrier aggregation bands is desired. In such applications, an acoustic filter can include shunt resonators of the shunt type and an acoustic resonator of the second type can be included as a series resonator by which other series resonators of the first type are coupled to a common port of the multiplexer. This can increase γ of the ladder filter 70 in the one or more higher frequency carrier aggregation bands. For example, in applications where the second input/output port PORT2 is a common port of a multiplexer, the series resonator RN can be a BAW resonator, other series resonators of the ladder filter 70 can be TCSAW resonators, and the shunt resonators R1 and RN−1 can be BAW resonators. By having the series resonator RN closest to the common node be a BAW resonator instead of a TCSAW resonator, y can be increased for the ladder filter 70 in one or more higher frequency carrier aggregation bands in such applications.

In some applications, the ladder filter 70 can be a transmit filter. In such applications, an acoustic resonator of the second type can be included as a series resonator by which other series resonators of the first type are coupled to a transmit port of the transmit filter. For example, in applications where the second input/output port PORT2 is a transmit port of a transmit filter, the series resonator RN can be a BAW resonator, other series resonators of the ladder filter 70 can be TCSAW resonators, and the shunt resonators R1 and RN−1 can be BAW resonators.

In certain applications, the ladder filter 70 can include more than two types of acoustic resonators. In such applications, the majority of the series resonators can be acoustic resonators of the first type (e.g., TCSAW resonators) and the majority of shunt resonators can be resonators of the second type (e.g., BAW resonators). The ladder filter 70 can include a third type of resonator as a shunt resonator and/or as a series resonator in such applications. The third type of resonator can be a Lamb wave resonator, for example. The acoustic wave filter 70 can include a plurality series resonators including temperature compensated surface acoustic wave resonators and a plurality shunt resonators including a Lamb wave resonator arranged as shunt resonator. The acoustic wave filter 70 can include a plurality of series resonators including a Lamb wave resonator and a plurality shunt resonators including bulk acoustic wave resonators arranged as shunt resonators.

FIG. 8 is a schematic diagram of a lattice filter 80. The lattice filter 80 is an example topology of a band pass filter formed from acoustic wave resonators. The lattice filter 80 can be arranged to filter an RF signal. As illustrated, the lattice filter 80 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 80 has a balanced input and a balanced output. The lattice filter 80 can be implemented with different type of acoustic resonators in accordance with any suitable principles and advantages disclosed herein. For example, the series resonators RL1 and RL2 can be TCSAW resonators and the shunt resonators RL3 and RLA can be BAW resonators for a bandpass filter. In particular, the TCSAW resonators may be formed with features of any one or more of the IDTs structures shown in FIG. 2A to FIG. 2D.

FIG. 9 is a schematic diagram of a hybrid ladder and lattice filter 90. The illustrated hybrid ladder and lattice filter includes series acoustic resonators RL1, RL2, RH3, and RH4 and shunt acoustic resonators RL3, RL4, RH1, and RH2. The hybrid ladder and lattice filter 90 can be implemented with different type of acoustic resonators in accordance with any suitable principles and advantages disclosed herein. For example, the series resonators RL1, RL2, RH3, and RH4 can be TCSAW resonators and the shunt resonators RL3, RL4, RH1, and RH2 can be BAW resonators for a bandpass filter. In particular, the TCSAW resonators may be formed with features of any one or more of the IDTs shown in FIG. 2A to FIG. 2D.

FIG. 10 is a schematic diagram of an acoustic filter 101 that includes ladder stages and a multi-mode surface acoustic wave filter 102. The illustrated acoustic filter 101 includes series resonators R2 and R4, shunt resonators R1 and R3, and multi-mode surface acoustic wave filter 102. The filter 101 can be a receive filter. The multi-mode surface acoustic wave filter 102 can be connected to a receive port. The multi-mode surface acoustic wave filter 102 includes longitudinally coupled IDT electrodes. The multi-mode surface acoustic wave filter 102 can include a temperature compensation layer over longitudinally coupled IDT electrodes in certain applications. The series resonators R2 and R4 can be TCSAW resonators and the shunt resonators R1 and R3 can be BAW resonators for a bandpass filter. The shunt resonators R1 and R3 being BAW resonators can help with lower skirt steepness and insertion loss. In particular, the TCSAW resonators may be formed with features of any one or more of the IDTs shown in FIG. 2A to FIG. 2D.

Acoustic filters disclosed herein include more than one type of acoustic wave resonator. Such filters can be implemented on a plurality of acoustic filter die. The plurality of acoustic filter die can be stacked and co-packaged with each other in certain applications.

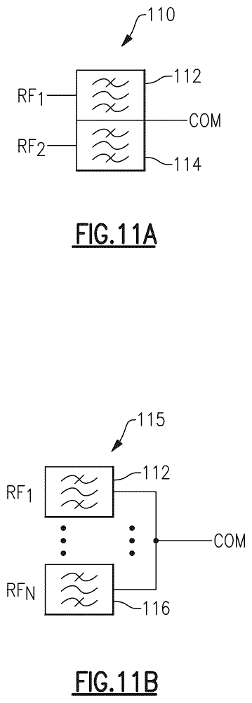

FIG. 11A is a schematic diagram of a duplexer 110 that includes an acoustic wave filter according to an embodiment. The duplexer 110 includes a first filter 112 and a second filter 114 coupled to together at a common node COM. One of the filters of the duplexer 110 can be a transmit filter and the other of the filters of the duplexer 110 can be a receive filter. The transmit filter and/or the receive filter can be respective ladder filters with acoustic wave resonators having a topology similar to the ladder filter 50 of FIG. 5 and the ladder filter 70 of FIG. 7. In some other instances, such as in a diversity receive application, the duplexer 110 can include two receive filters. The common node COM can be an antenna node.

The first filter 112 is an acoustic wave filter arranged to filter a radio frequency signal. The first filter 112 can include acoustic wave resonators coupled between a first radio frequency node RF1 and the common node. The first radio frequency node RF1 can be a transmit node or a receive node. The first filter 112 includes two types of acoustic resonators in accordance with any suitable principles and advantages disclosed herein.

The second filter 114 can be any suitable filter arranged to filter a second radio frequency signal. The second filter 114 can be, for example, an acoustic wave filter, an acoustic wave filter that includes two types of acoustic resonators, an LC filter, a hybrid acoustic wave LC filter, or the like. The second filter 114 is coupled between a second radio frequency node RF2 and the common node. The second radio frequency node RF2 can be a transmit node or a receive node.

Although example embodiments may be discussed with filters or duplexers for illustrative purposes, any suitable the principles and advantages disclosed herein can be implemented in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. One or more filters of a multiplexer can include an acoustic wave filter including two types of acoustic resonators in accordance with any suitable principles and advantages disclosed herein.

FIG. 11B is a schematic diagram of a multiplexer 115 that includes an acoustic wave filter according to an embodiment. The multiplexer 115 includes a plurality of filters 112 to 116 coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters.

The first filter 112 is an acoustic wave filter arranged to filter a radio frequency signal. The first filter 112 can include acoustic wave resonators coupled between a first radio frequency node RF1 and the common node. The first radio frequency node RF1 can be a transmit node or a receive node. The first filter 112 includes two types of acoustic resonators in accordance with any suitable principles and advantages disclosed herein. The other filter(s) of the multiplexer 115 can include one or more acoustic wave filters, one or more acoustic wave filters that include two types of acoustic resonators in accordance with any suitable principles and advantages disclosed herein, one or more LC filters, one or more hybrid acoustic wave LC filters, or any suitable combination thereof.

The acoustic wave filters disclosed herein can be implemented in a variety of packaged modules. In particular, acoustic wave filters disclosed herein may be formed with features of any one or more of the IDTs shown in FIG. 2A to FIG. 2D. Some example packaged modules will now be disclosed in which any suitable principles and advantages of the acoustic wave filters and/or acoustic wave resonators disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 20 to 24 are schematic block diagrams of illustrative packaged modules according to certain embodiments. Any suitable combination of features of these packaged modules can be implemented with each other. While duplexers are illustrated in the example packaged modules of FIGS. 21, 22, and 24, any other suitable multiplexer that includes a plurality of filters coupled to a common node and/or standalone filter can be implemented instead of one or more duplexers. For example, a triplexer can be implemented in certain applications. As another example, one or more filters of a packaged module can be arranged as a transmit filter or a receive filter that is not included in a multiplexer.

FIG. 12 is a schematic diagram of a radio frequency module 200 that includes an acoustic wave component 202 according to an embodiment. The illustrated radio frequency module 200 includes the acoustic wave component 202 and other circuitry 203. The acoustic wave component 202 can include one or more acoustic wave filters in accordance with any suitable combination of features of the acoustic wave filters disclosed herein. The acoustic wave component 202 can include an acoustic wave filter with series TCSAW resonators and shunt BAW resonators, for example.

The acoustic wave component 202 shown in FIG. 12 includes one or more acoustic wave filters 204 and terminals 205A and 205B. The one or more acoustic wave filters 204 includes an acoustic wave filter implemented in accordance with any suitable principles and advantages disclosed herein. The terminals 205A and 204B can serve, for example, as an input contact and an output contact. Although two terminals are illustrated, any suitable number of terminals can be implemented for a particular application. The acoustic wave component 202 and the other circuitry 203 are on a common packaging substrate 206 in FIG. 12. The package substrate 206 can be a laminate substrate. The terminals 205A and 205B can be electrically connected to contacts 207A and 207B, respectively, on the packaging substrate 206 by way of electrical connectors 208A and 208B, respectively. The electrical connectors 208A and 208B can be bumps or wire bonds, for example.

The other circuitry 203 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. The other circuitry 203 can be electrically connected to the one or more acoustic wave filters 204. The radio frequency module 200 can include one or more packaging structures to, for example, provide protection and/or facilitate easier handling of the radio frequency module 200. Such a packaging structure can include an overmold structure formed over the packaging substrate 206. The overmold structure can encapsulate some or all of the components of the radio frequency module 200.

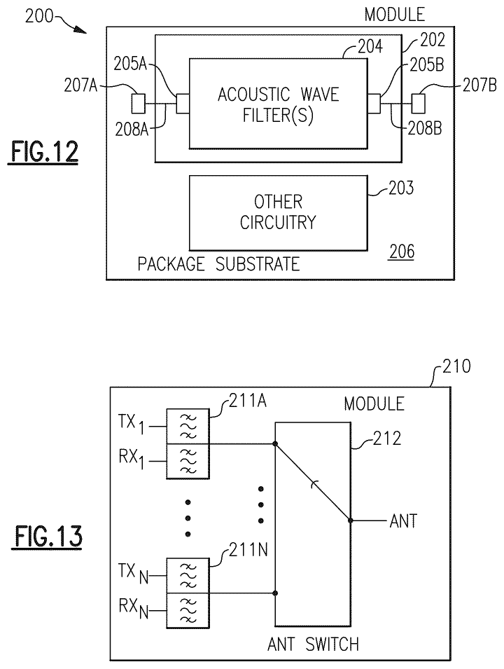

FIG. 13 is a schematic block diagram of a module 210 that includes duplexers 211A to 211N and an antenna switch 212. One or more filters of the duplexers 211A to 211N can include an acoustic wave filter in accordance with any suitable principles and advantages disclosed herein. Any suitable number of duplexers 211A to 211N can be implemented. The antenna switch 212 can have a number of throws corresponding to the number of duplexers 211A to 211N. The antenna switch 212 can include one or more additional throws coupled to one or more filters external to the module 210 and/or coupled to other circuitry. The antenna switch 212 can electrically couple a selected duplexer to an antenna port of the module 210.

FIG. 14 is a schematic block diagram of a module 220 that includes a power amplifier 222, a radio frequency switch 224, and duplexers 211A to 211N according to an embodiment. The power amplifier 222 can amplify a radio frequency signal. The radio frequency switch 224 can be a multi-throw radio frequency switch. The radio frequency switch 224 can electrically couple an output of the power amplifier 222 to a selected transmit filter of the duplexers 211A to 211N. One or more filters of the duplexers 211A to 211N can be an acoustic wave filter in accordance with any suitable principles and advantages disclosed herein. Any suitable number of duplexers 211A to 211N can be implemented.

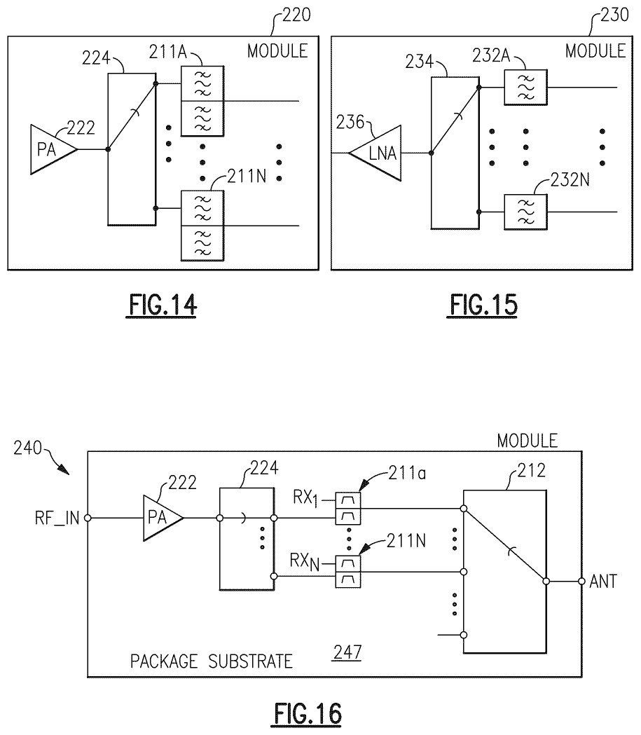

FIG. 15 is a schematic block diagram of a module 230 that includes filters 232A to 232N, a radio frequency switch 234, and a low noise amplifier 236 according to an embodiment. One or more filters of the filters 232A to 232N can include any suitable number of acoustic wave filters in accordance with any suitable principles and advantages disclosed herein. Any suitable number of filters 232A to 232N can be implemented. The illustrated filters 232A to 232N are receive filters. In some embodiments (not illustrated), one or more of the filters 232A to 232N can be included in a multiplexer that also includes a transmit filter. The radio frequency switch 234 can be a multi-throw radio frequency switch. The radio frequency switch 234 can electrically couple an output of a selected filter of filters 232A to 232N to the low noise amplifier 236. In some embodiments (not illustrated), a plurality of low noise amplifiers can be implemented. The module 230 can include diversity receive features in certain applications.

FIG. 16 is a schematic diagram of a radio frequency module 240 that includes an acoustic wave filter according to an embodiment. As illustrated, the radio frequency module 240 includes duplexers 211A to 211N, a power amplifier 222, a select switch 224, and an antenna switch 212. The radio frequency module 240 can include a package that encloses the illustrated elements. The illustrated elements can be disposed on a common packaging substrate 247. The packaging substrate 247 can be a laminate substrate, for example. A radio frequency module that includes a power amplifier can be referred to as a power amplifier module. A radio frequency module can include a subset of the elements illustrated in FIG. 16 and/or additional elements. The radio frequency module 240 may include any one of the acoustic wave filters in accordance with any suitable principles and advantages disclosed herein.

The duplexers 211A to 211N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave filter in accordance with any suitable principles and advantages disclosed herein. Similarly, one or more of the receive filters can include an acoustic wave filter in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switch-plexers and/or with standalone filters.

The power amplifier 222 can amplify a radio frequency signal. The illustrated switch 224 is a multi-throw radio frequency switch. The switch 224 can electrically couple an output of the power amplifier 222 to a selected transmit filter of the transmit filters of the duplexers 211A to 211N. In some instances, the switch 224 can electrically connect the output of the power amplifier 222 to more than one of the transmit filters. The antenna switch 212 can selectively couple a signal from one or more of the duplexers 211A to 211N to an antenna port ANT. The duplexers 211A to 211N can be associated with different frequency bands and/or different modes of operation (e.g., different power modes, different signaling modes, etc.).

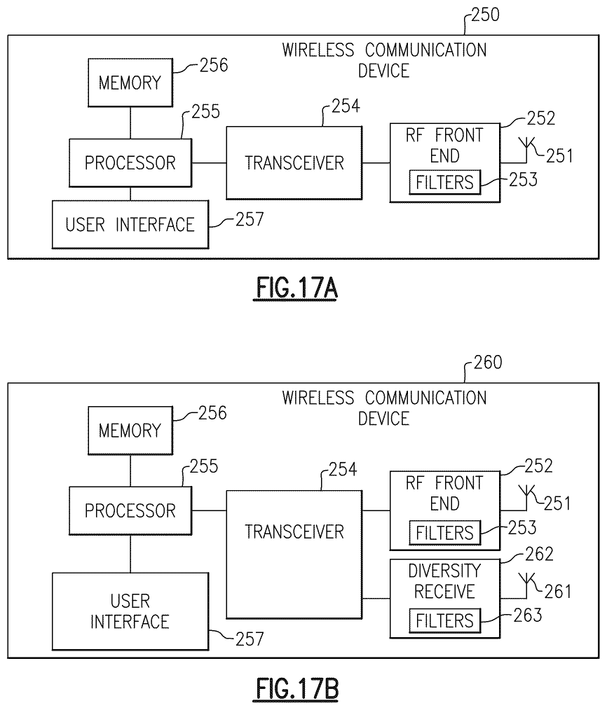

The acoustic wave filters disclosed herein can be implemented in a variety of wireless communication devices. FIG. 17A is a schematic diagram of a wireless communication 250 device that includes filters 253 in a radio frequency front end 252 according to an embodiment. One or more of the filters 253 can be acoustic wave filter in accordance with any suitable principles and advantages disclosed herein. The wireless communication device 250 can be any suitable wireless communication device. For instance, a wireless communication device 250 can be a mobile phone, such as a smart phone. As illustrated, the wireless communication device 250 includes an antenna 251, an RF front end 252, a transceiver 254, a processor 255, a memory 256, and a user interface 257. The antenna 251 can transmit RF signals provided by the RF front end 252. Such RF signals can include carrier aggregation signals. The antenna 251 can receive RF signals and provide the received RF signals to the RF front end 252 for processing. Such RF signals can include carrier aggregation signals. The wireless communication device 250 can include two or more antennas in certain instances.

The RF front end 252 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 252 can transmit and receive RF signals associated with any suitable communication standards. One or more of the filters 253 can include an acoustic wave filter with two types of acoustic resonators that includes any suitable combination of features of the embodiments disclosed above.

The transceiver 254 can provide RF signals to the RF front end 252 for amplification and/or other processing. The transceiver 254 can also process an RF signal provided by a low noise amplifier of the RF front end 252. The transceiver 254 is in communication with the processor 255. The processor 255 can be a baseband processor. The processor 255 can provide any suitable base band processing functions for the wireless communication device 250. The memory 256 can be accessed by the processor 255. The memory 256 can store any suitable data for the wireless communication device 250. The user interface 257 can be any suitable user interface, such as a display with touch screen capabilities.

FIG. 17B is a schematic diagram of a wireless communication device 260 that includes filters 253 in a radio frequency front end 252 and second filters 263 in a diversity receive module 262. The wireless communication device 260 is like the wireless communication device 250 of FIG. 17A, except that the wireless communication device 260 also includes diversity receive features. As illustrated in FIG. 17B, the wireless communication device 260 includes a diversity antenna 261, a diversity module 262 configured to process signals received by the diversity antenna 261 and including filters 263, and a transceiver 254 in communication with both the radio frequency front end 252 and the diversity receive module 262. One or more of the second filters 263 can include an acoustic wave filter in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ.

An acoustic wave filter including any suitable combination of features disclosed herein be arranged to filter a radio frequency signal in a 5G NR operating band within Frequency Range 1 (FR1). A filter arranged to filter a radio frequency signal in a 5G NR operating band can include two types of acoustic resonators in accordance with any principles and advantages disclosed herein. FRI can be from 410 MHz to 7.125 GHZ, for example, as specified in a current 5G NR specification. In 5G applications, an acoustic wave filter with a relatively wide pass band and relatively low insertion loss can be advantageous for implementing dual connectivity. An acoustic wave filter in accordance with any suitable principles and advantages disclosed herein can be arranged to filter a radio frequency signal in a 4G LTE operating band and/or in a filter having a passband that includes a 4G LTE operating band and a 5G NR operating band. Filters disclosed herein can filter radio frequency signals in a frequency range from about 400 MHz to 3 GHz in certain applications.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly coupled, or coupled by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A ladder filter comprising:
an input port and an output port;
a shunt surface acoustic wave resonator coupled between the input port and the output port and including a piezoelectric layer and an interdigital transducer structure;
a series surface acoustic wave resonator coupled between the input port and the output port and including a piezoelectric layer, an interdigital transducer structure; and
a capacitor coupled in parallel with the series surface acoustic wave resonator, the capacitor resulting in a shifted anti-resonant frequency for the series surface acoustic wave resonator.

2. The ladder filter of claim 1 wherein the capacitor has capacitance in a range between 0.1 and 3.9 pF.

3. The ladder filter of claim 1 wherein the capacitor and the interdigital transducer structure are separated by one or more reflectors.

4. The ladder filter of claim 1 wherein the capacitor and the interdigital transducer structure are formed in a same plane on the piezoelectric layer.

5. The ladder filter of claim 1 wherein the capacitor has fingers that are parallel or rotated with respect to fingers of the interdigital transducer structure.

6. The ladder filter of claim 1 wherein the capacitor and the interdigital transducer structure are formed in different planes on the piezoelectric layer.

7. The ladder filter of claim 1 wherein the interdigital transducer structure is at least partially embedded in the piezoelectric layer.

8. The ladder filter of claim 7 wherein the interdigital transducer structure has an embedment depth d_{embed} in a range between 0.01λ and 0.1λ, where λ is a wavelength along an interdigital transducer propagation direction of a main mode.

9. The ladder filter of claim 7 wherein the interdigital transducer structure is fully embedded in the piezoelectric layer.

10. An acoustic wave filter package comprising:
a package;
a surface acoustic wave resonator within the package including a piezoelectric layer and an interdigital transducer structure; and
a capacitor within the package and coupled in parallel with the surface acoustic wave resonator, the capacitor resulting in a shifted anti-resonant frequency.

11. The acoustic wave filter package of claim 10 wherein the capacitor has capacitance in a range between 0.1 and 3.9 pF.

12. The acoustic wave filter package of claim 10 wherein the capacitor and the interdigital transducer structure are separated by one or more reflectors.

13. The acoustic wave filter package of claim 10 wherein the capacitor and the interdigital transducer structure are formed in a same plane on the piezoelectric layer.

14. The acoustic wave filter package of claim 10 wherein the capacitor has fingers that are parallel or rotated with respect to fingers of the interdigital transducer structure.

15. The acoustic wave filter package of claim 10 wherein the capacitor and the interdigital transducer structure are formed in different planes on the piezoelectric layer.

16. The acoustic wave filter package of claim 10 wherein the interdigital transducer structure is at least partially embedded in the piezoelectric layer.

17. The acoustic wave filter package of claim 16 wherein the interdigital transducer structure has an embedment depth d_{embed} in a range between 0.01λ and 0.1λ, where λ is a wavelength along an interdigital transducer propagation direction of a main mode.

18. The acoustic wave filter package of claim 16 wherein the interdigital transducer structure is fully embedded in the piezoelectric layer.

19. A mobile device comprising:
a transceiver;
an acoustic wave filter including a surface acoustic wave resonator including a piezoelectric layer and an interdigital transducer structure and further including a capacitor coupled in parallel with the surface acoustic wave resonator, the capacitor resulting in a shifted anti-resonant frequency; and
an antenna.

20. The mobile device of claim 19 wherein the surface acoustic wave resonator is a series acoustic wave filter, the acoustic wave filter further comprising a shunt acoustic wave filter arranged in a ladder filter structure with the series acoustic wave filter.
